(19) United States
(12) Patent Application Publication
(10) Pub. No.: US 2024/0219842 A1
(43) Pub. Date: Jul. 4, 2024

(54) Photoresist developer

(71) Applicants: Manish Chandhok, Beaverton, OR (US); Wang Yueh, Portland, OR (US); Heidi Cao, Portland, OR (US)

(72) Inventors: Manish Chandhok, Beaverton, OR (US); Wang Yueh, Portland, OR (US); Heidi Cao, Portland, OR (US)

(21) Appl. No.: 10/956,321

(22) Filed: Sep. 30, 2004

(51) Int. Cl. G03F 7/32; G03F 7/16

(52) U.S. Cl. CPC G03F 7/322; G03F 7/162

(57) ABSTRACT

Numerous embodiments of a method for developing a photoresist material are described. In one embodiment of the present invention, a photoresist layer is disposed over a substrate. The photoresist layer has a bulk region to form a first region and a second region. A photoresist developer made of a tetra-alkyl ammonium hydroxide compound is applied to the photoresist layer to react only with substantial portions of the first region and to prevent penetration of the developer solution into the bulk portion near the second region.

### FIELD

Embodiments of the present invention relate to photolithography of semiconductor devices, and more particularly, to the use of a photoresist developer.

### BACKGROUND

Manufacture of semiconductor devices typically involves a series of processes in which various layers are deposited and patterned on a substrate to form a device of the desired type. Line and space patterns in photoresist are often created to form microelectronic devices. Smaller critical dimensions (CD) for both lines and spaces allow faster circuitry to be created.

Photolithography is commonly used in a semiconductor manufacturing process to form patterns on a semiconductor wafer. In the photolithography process, a photoresist layer is deposited over an underlying layer that is to be etched. The photoresist layer is then selectively exposed to radiation through a mask. The photoresist layer is then developed with a photoresist developer, and in the case of a positive photoresist those portions of the photoresist exposed to the radiation are removed.

For a positive-tone photoresist, a tetra methyl ammonium hydroxide (TMAH) aqueous solution is a common developer that will enhance dissolution of the exposed photoresist. One problem with typical developer solutions such as TMAH is that the developer solution may penetrate into the areas of the photoresist that have not been exposed to radiation, thereby removing polymer chains and aggregates, as illustrated in FIG. 1. This results in a “rough” surface pattern for the photoresist layer and high line edge roughness (LER). Line width roughness (LWR) is the LER contribution from the two edges of a line resulting in the line width variation.

When the LWR is large (e.g., more than 5% of the CD), device performance may be impacted. For example, the impact on the device is similar to having multiple features of varying CDs in parallel (along the width of the device). The problem is that when the feature sizes are scaled, the line edge roughness (LER) does not scale with line width. A number of factors may influence LWR, for instance, the size of the molecules in the polymer backbone used in the photoresist is at a finite size to meet other requirements (e.g., mechanical strength), and the size of the polymer molecule will limit the LER percentage.

### BRIEF DESCRIPTION OF THE DRAWINGS

Embodiments of the present invention are illustrated by way of example, and not limitation, in the figures of the accompanying drawings in which:

FIG. 1 illustrates a simplified view of a photoresist developer that penetrates into the photoresist layer.

FIG. 2 illustrates a cross-sectional view of a photoresist coated substrate that is partially blocked from radiation exposure by a mask.

FIG. 3 illustrates the structure of FIG. 2 after light exposure, removal of the mask, introduction of a developer, and dissolution of the photoresist in the exposed areas due to development.

FIG. 4 illustrates a simplified view of a developer solution applied over photoresist material in one embodiment of the present invention.

FIG. 5 illustrates the photoresist layer of FIG. 4 after the developer solution has been applied to remove only a surface region.

FIG. 6 illustrates a hydroxyl organic compound, tetra-alkyl ammonium hydroxide, that may be used for the developer solution in one embodiment of the present invention.

FIG. 7 illustrates the structure of 1-azoniaproellane hydroxide, which may be used for the developer solution in one embodiment of the present invention.

FIG. 8 illustrates a block diagram of one method of the present invention.

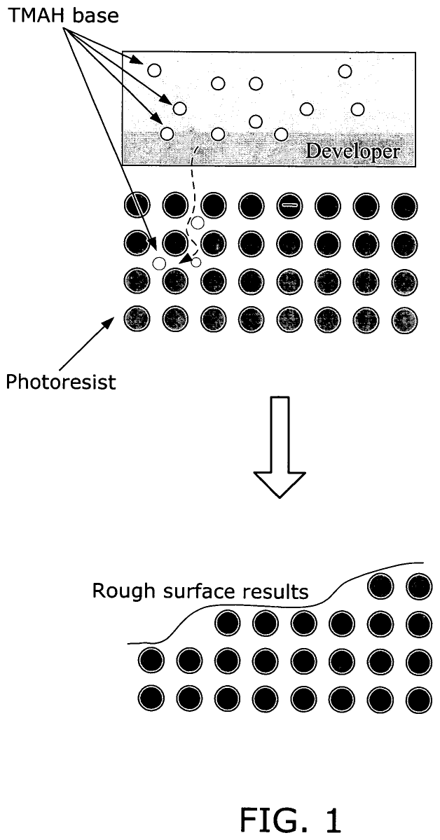

### DETAILED DESCRIPTION

In the following description, numerous specific details are set forth such as examples of specific materials or components in order to provide a thorough understanding of embodiments of the present invention. It will be apparent, however, to one skilled in the art that these specific details need not be employed to practice embodiments of the present invention. In other instances, well known components, methods, semiconductor equipment and processes have not been described in detail in order to avoid unnecessarily obscuring embodiments of the present invention.

The terms “on,” “above,” “below,” “between,” or “above” as used herein refer to a relative position of one layer or element with respect to other layers or elements. As such, a first element disposed on, above or below another element may be directly in contact with the first element or may have one or more intervening elements. Moreover, one element disposed next to or adjacent another element may be directly in contact with the first element or may have one or more intervening elements.

Any reference in the specification to “one embodiment” or “an embodiment” means that a particular feature, structure, or characteristic described in connection with the embodiment is included in at least one embodiment of the claimed subject matter. The appearances of the phrase, “in one embodiment” in various places in the specification are not necessarily all referring to the same embodiment.

Embodiments of a method to develop a photoresist layer are disclosed. In one embodiment of the present invention, a photolithography process forms a pattern on the photoresist layer that includes a first region exposed to radiation energy and a second region not exposed to radiation energy. A developer solution made of a tetra alkyl ammonium hydroxide (TANOH) compound is applied to the photoresist layer. When applied to the photoresist layer, the developer solution removes substantial portions of the first region. However, the relatively large size of the TANOH compound is unable to penetrate into the second region of the photoresist layer, and may react only with the photoresist material on the surface of the photoresist layer. This produces a photoresist layer having a smoother surface after development with low LER.

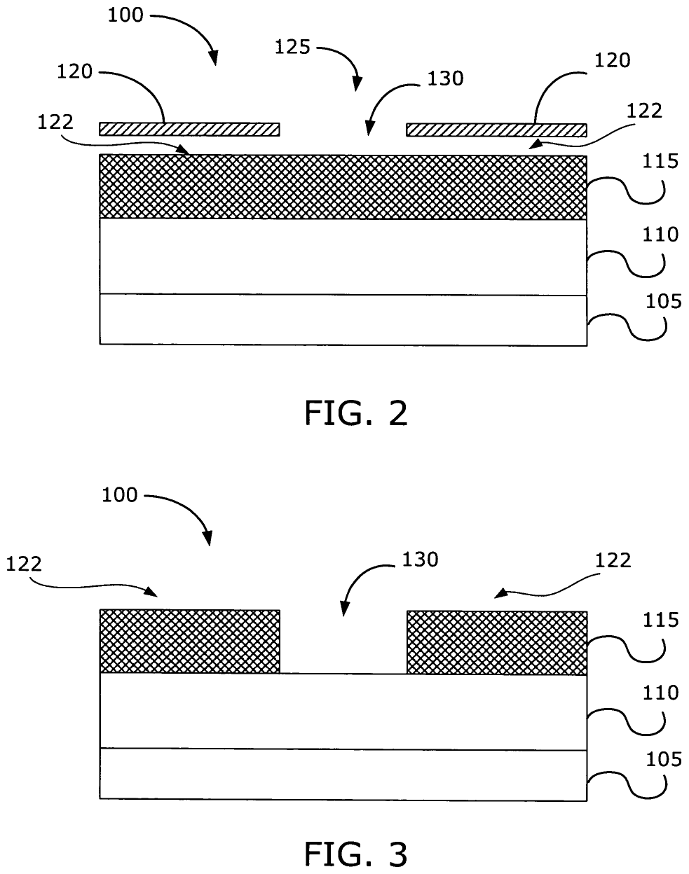

FIG. 2 illustrates a cross-sectional view of a partially processed circuit structure 100 in one embodiment of the present invention. Circuit structure 100 includes substrate 105 that may be a wafer substrate having circuit elements thereon, as well as one or more layers or levels of interconnection to circuit elements. Substrate 105 may also be a wafer upon which other manufacturing and processing operations may be performed so as to form various electrical components, including but limited to, transistors, as well as conductive interconnections. A dielectric material/layer 110 may be disposed or deposited above substrate 105. Dielectric material 110 may be, for example, silicon dioxide (SiO₂) formed by a tetraethyl orthosilicate deposition process. Other suitable materials for dielectric material 110 may be contemplated, including materials having dielectric constants less than the dielectric constant of SiO₂ (e.g., “low k” materials), including polymers.

In one embodiment, structure 100 is prepared as part of a patterning operation, and in particular, a photolithography operation to define a portion of a photoresist material to be removed. FIG. 2 illustrates a photolithography process using a positive photoresist methodology. A relatively non-soluble photoresist material or layer 115 is disposed over dielectric material 110, for example, by a spin-coating process as known in the art. Following the introduction of photoresist material 115, mask 120 is aligned over structure 100 defining opening 125 on mask 120 for light exposure to pass through and encode an image in photoresist material 115. Mask 120 may be, for example, any type of masking material known in the art. Having properly aligned mask 120 over structure 100, structure 100 is exposed to a radiation source, such as an ultraviolet light (not shown). In one embodiment, light from the light source passes through opening 125 of mask 120. Region 122 of photoresist material 115 is shielded by mask 120 is not exposed to the ultraviolet light. The light that passes through opening 125 contacts photoresist material 115 in region 130 exposed by opening 125 of mask 120. The light changes the chemical structure of photoresist material 115 in exposed region 130 from relatively non-soluble to much more soluble. In chemically amplified photoresists, the effect of incident radiation is to generate a photoacid. The photoacid serves as a catalyst for deprotection reaction that occurs during the post-exposure bake (PEB) process. After PEB, deprotected regions can be removed easily during the developer process.

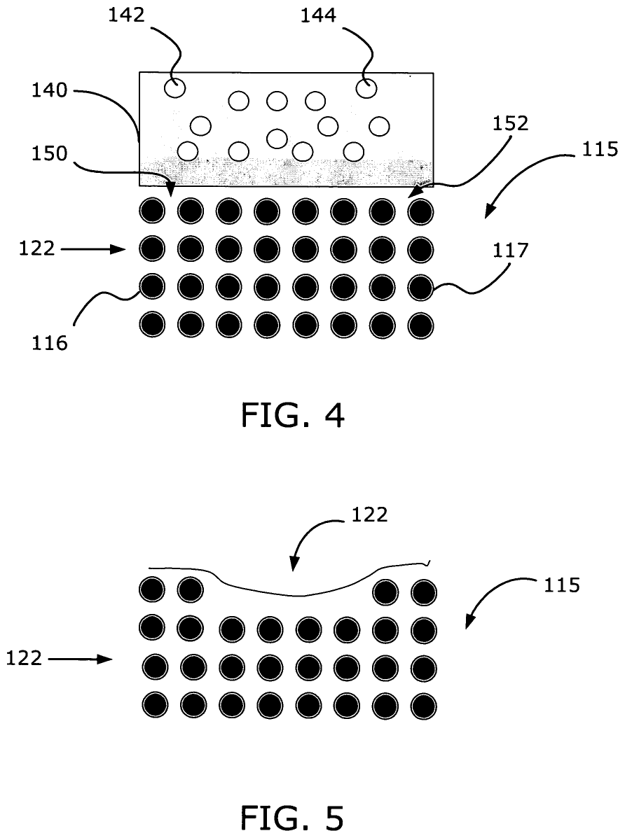

Following PEB, a photoresist developer (not shown) may be applied to remove the deprotected photoresist material 115 in region 130, while retaining the generally insoluble photoresist material over substrate 105 in region 122 that was not exposed to light from the light source and/or areas in the bulk portion of photoresist material 115. As described in greater detail below with respect to FIGS. 4-5, photoresist material 115 near exposed region 130 may be more polar. In some instances, carboxylic acid or hydroxyl groups may be formed upon deprotection of photoresist material 115. Any reaction of the photoresist material near region 122 with the developer solution is limited to a surface region near region 122. In one embodiment, any amount of photoresist material that may be removed near region 122 (i.e., the unexposed region) may be limited to the surface regions. That is, any reaction of the developer solution with photoresist material near region 122 occurs on the surface only, which prevents the formation of a rough surface for the photoresist material near region 122. Alternatively, the developer solution does not react with any portion of photoresist material near region 122. FIG. 3 illustrates structure 100 after light exposure, removal of mask 120, and the introduction of a developer. As shown, the reaction of the developer with the photoresist material near region 122 is limited, where little to no amount of photoresist material is removed (i.e., only deprotected regions on the surface of photoresist material are removed). As a result, the photoresist material 122 possesses a relatively smooth surface with sharp edges.

FIG. 4 illustrates a simplified view of a developer solution 140 applied over region 122 of photoresist material 115 in one embodiment of the present invention. Photoresist material 115 may be composed primarily of polymers (about 80% to about 90%) both along the top surface and throughout the bulk of photoresist material 115. Photoresist polymers are represented by polymers 116, 117. The surface layer of photoresist material 115 also includes pores (e.g., 150, 152) or gaps between the polymers. Developer 140, in one embodiment, is a substantially hydroxyl solution made of compounds (e.g., compounds 142, 144) having a size larger than that of the pores on the surface of photoresist layer 115. As such, the developer compounds cannot penetrate through the surface of photoresist layer 115 and react with the regions (i.e., polymers) below the surface layer, preventing the removal of photoresist material 115 in the bulk regions (i.e., beyond the surface) near region 122.

FIG. 5 illustrates region 122 of photoresist layer 115 after contact with developer solution 140 has been made. In one embodiment, any removal of photoresist material is limited to the acidic regions (i.e., polarized) near the top surface of photoresist material 115. The removal of photoresist material generally occurs through an acid-base reaction. The hydroxide ions spread across the top surface of the photoresist material. The hydroxide ions of the developer solution then deprotonates the acidic regions of the photoresist polymer via acid-base reactions. The acid-base reaction may be represented as:

$$POH + {OH}^{-} \to {PO}^{-} + {H}_{2} O$$

in which P represents the photoresist polymer.

After the reaction is completed, the polymer may be absorbed or dissolved into the bulk of the developer solution.

The use of a large compound developer solution prevents any reaction in the bulk regions of the photoresist material, because the developer solution cannot fit through the pores or gaps of the photoresist material. As discussed above, any reaction with the developer solution may occur only with regions on the surface of the photoresist material. This produces a photoresist layer having a smooth surface, and subsequently a photoresist having a lower LER, in contrast to a photoresist developed with a solution having compounds small enough to penetrate into the bulk regions of region 122.

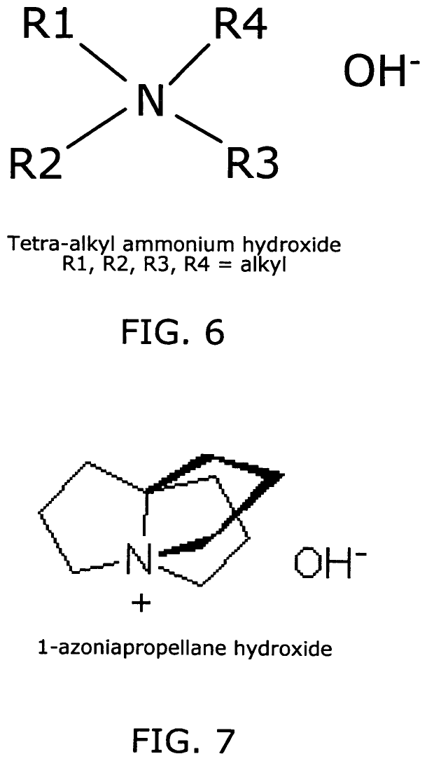

In one embodiment, the size of hydroxyl compounds (e.g., 142, 144) in developer solution 140 may be increased by forming linear or caged hydroxyl organic compounds. FIG. 6 illustrates one embodiment of a hydroxyl organic compound, tetra-alkyl ammonium hydroxide, that may be used for developer solution 140 and having the general formula:

$$R 4 NOH$$

where R is an alkyl group.

Examples of tetra-alkyl ammonium hydroxide compounds include, but is not limited to, tetra-n-butyl ammonium hydroxide, tetra-t-butyl ammonium hydroxide, and tetra-isopropyl ammonium hydroxide. In one embodiment, the alkyl group of the tetra-alkyl ammonium hydroxide compound may have at least two carbon groups to form the linear structure. In an alternative embodiment, the hydroxyl organic compound may be 1-azoniaproellane hydroxide, as illustrated in FIG. 7. It may be appreciated that other long chain and/or bulky (i.e., 3-12 member rings, caged) compounds may be used for developer solution 140. The concentration of those developers may be from about 0.05% to about 10% (weight percentage).

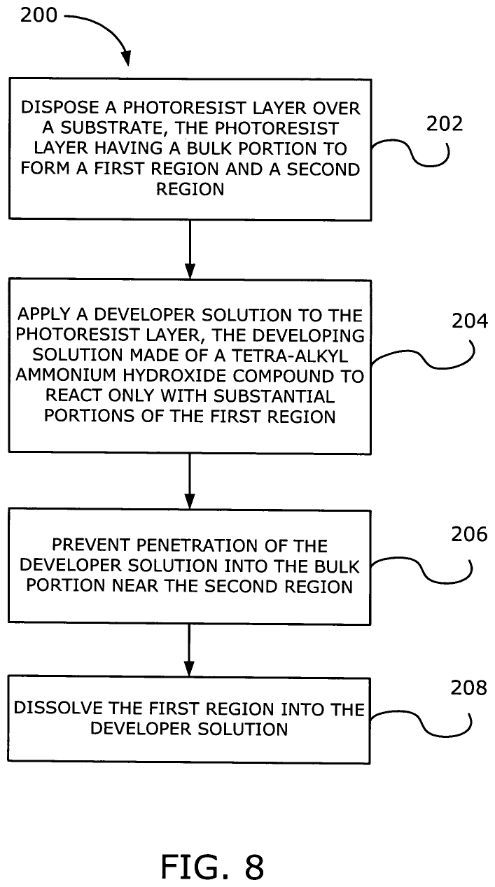

FIG. 8 illustrates a block diagram 200 of one method of the present invention. A photoresist layer (e.g., photoresist layer 115) or material is disposed over a substrate (e.g., substrate 105), block 202. In one embodiment, the photoresist layer may be spin-coated on the substrate. The photoresist layer may have a structure that includes a bulk portion that forms a first region and a second region (e.g., first region 130 and second region 122). The surface of the first region may be exposed to a light source as part of a masking photolithography process, while the second region is shielded by the mask. Following the light exposure, a developer solution may be applied to the surface of the photoresist layer, block 204. In one embodiment of the present invention, the developer solution may be made of a tetra-alkyl ammonium hydroxide compound (e.g., as illustrated in FIG. 6). This hydroxyl organic compound reacts only with substantial portions of the first region (e.g., polarized regions). Any penetration of the developer compound into the bulk portion near the second region is prevented, block 206.

The tetra-alkyl ammonium hydroxide compound may have a linear or caged structure that has a size that is too large to penetrate through the surface of the photoresist layer near the second region. That is, the developer compound solution cannot pass through any pores or gaps formed by the photoresist polymer near the second region. Alternatively, any reaction of the developer compound solution with the photoresist layer near the second region occurs near the surface only (e.g., any polarized regions on the surface). In one embodiment, the tetra-alkyl ammonium hydroxide compound (e.g., as illustrated in FIG. 6) may be tetra-n-butyl ammonium hydroxide, tetra-t-butyl ammonium hydroxide, tetra-isopropyl ammonium hydroxide, and 1-azoniaproellane hydroxide. The reaction of the developer compound with the first region may result in substantial portions of the region being dissolved into the developer solution, block 208.

The use of a developer solution with compounds that have a size greater than any gaps or pores formed on the surface of the second region of the photoresist layer generates a relatively smooth photoresist surface (as illustrated in FIG. 5). This results in a photoresist having a lower LER relative to a photoresist developed with a solution having compounds small enough to penetrate into the bulk areas of photoresist material.

In the foregoing specification, the invention is described with reference to specific embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed is:

1. A method, comprising:
disposing a photoresist layer over a substrate, the photoresist layer having a bulk region to form a first region and a second region;
applying a developer solution to the photoresist layer, the developer solution made of a tetra-alkyl ammonium hydroxide compound to react only with substantial portions of the first region and to prevent penetration of the developer solution into the bulk portion near the second region; and
absorbing the first region into the developer solution.

2. The method of claim 1, wherein applying further comprises reacting the tetra-alkyl ammonium hydroxide with polar regions of the first portion of the photoresist layer, the tetra-alkyl ammonium hydroxide having the general formula:
$$R 4 NOH$$
where R is an alkyl group having at least two carbon groups.

3. The method of claim 2, wherein the hydroxyl compound comprises tetra-n-butyl ammonium hydroxide.

4. The method of claim 2, wherein the hydroxyl compound comprises tetra-t-butyl ammonium hydroxide.

5. The method of claim 2, wherein the hydroxyl compound comprises tetra-isopropyl ammonium hydroxide.

6. The method of claim 2, wherein the hydroxyl compound comprises 1-azoniaproellane hydroxide.

7. The method of claim 1, wherein disposing further comprises exposing a light source to the first region of the photoresist layer.

8. The method of claim 1, wherein disposing further comprises spin-coating the photoresist layer on the substrate.

9. A method, comprising:
disposing a photoresist polymer over a substrate, the photoresist polymer having a structure that includes a first region, a second region, a bulk, and pores formed on a surface; and
developing the photoresist polymer with a photoresist developer to remove a substantial portion of the first region selectively, the photoresist developer made of a hydroxyl compound that has a size larger than the pores to prevent passage through the surface and into the second region.

10. The method of claim 9, wherein developing further comprises reacting the hydroxyl compound with polar regions of the first region of the photoresist polymer to remove portions of the photoresist polymer.

11. The method of claim 9, wherein the hydroxyl compound comprises a tetra-alkyl ammonium hydroxide having the general formula:
$$R 4 NOH$$
where R is an alkyl group having at least two carbon groups.

12. The method of claim 11, wherein the hydroxyl compound comprises tetra-n-butyl ammonium hydroxide.

13. The method of claim 11, wherein the hydroxyl compound comprises tetra-t-butyl ammonium hydroxide.

14. The method of claim 11, wherein the hydroxyl compound comprises tetra-isopropyl ammonium hydroxide.

15. The method of claim 11, wherein the hydroxyl compound comprises 1-azoniaproellane hydroxide.

16. The method of claim 10, wherein developing further comprises dissolving the first region into the photoresist developer.

17. A method, comprising:
disposing a dielectric layer over a substrate;
disposing a photoresist layer over the dielectric layer, the photoresist layer having a bulk portion having a first region, a second region, and a top surface;
disposing a patterned mask over the top surface of the photoresist layer to expose the first region;
exposing the first region to radiation; and
applying a developer solution to the photoresist layer, the developer solution made of a tetra-alkyl ammonium hydroxide compound to react only with the first region to remove a substantial portion of the first region and to prevent penetration of the developer solution into the bulk portion through the second region.

18. The method of claim 17, wherein disposing the photoresist layer further comprises forming the photoresist layer having a structure that includes a pores formed on a surface of the photoresist layer, and wherein the tetra-alkyl ammonium hydroxide compound has a size larger than the pores.

19. The method of claim 18, wherein the tetra-alkyl ammonium hydroxide compound has the general formula:
$$R 4 NOH$$
where R is an alkyl group having at least two carbon groups.

20. The method of claim 18, wherein the tetra-alkyl ammonium hydroxide compound comprises tetra-n-butyl ammonium hydroxide.

21. The method of claim 18, wherein the tetra-alkyl ammonium hydroxide compound comprises tetra-t-butyl ammonium hydroxide.

22. The method of claim 18, wherein the tetra-alkyl ammonium hydroxide compound comprises tetra-isopropyl ammonium hydroxide.

23. The method of claim 18, wherein the tetra-alkyl ammonium hydroxide compound comprises 1-azoniaproellane hydroxide.
